(19) United States
(12) Patent Application Publication
(10) Pub. No.: US 2004/0145865 A1
(43) Pub. Date: Jul. 29, 2004

(54) Electronic device with display and sensor

(76) Inventor: Che-Li Lin, Taipei (TW)

Correspondence Address: QUINTERO LAW OFFICE, 1617 BROADWAY, 3RD FLOOR, SANTA MONICA, CA, 90404, US

(21) Appl. No.: 10/757,681

(22) Filed: Jan. 14, 2004

(30) Foreign Application Priority Data
Jan. 20, 2003 (TW) 92200961

(51) Int. Cl. H05K 5/00

(52) U.S. Cl. 361/683

(57) ABSTRACT

An electronic device. The device includes a body, a rotating member, a first display, and a sensor. The rotating member is rotatably connected to the body. The rotating member has first and second surfaces. The first display is disposed on the first surface of the rotating member. The sensor is disposed on the second surface of the rotating member, and allows capture of images form multiple angles when the rotating member is rotated.

### BACKGROUND OF THE INVENTION

1. Field of the Invention

The present invention relates in general to an electronic device with display and sensor. In particular, the present invention relates to an electronic device with display and sensor integrally formed on a rotating member.

2. Description of the Prior Art

Currently, many electronics, such as mobile phones, are integrated with large multicolored display and sensor as standard features. When the multicolored display displays several messages, such as signal level, time and battery level, power is continuously supplied thereto. Thus, standby time is reduced, and the display may be easily damaged.

A mobile phone may also be equipped with a CCD or a CMOS sensor. A multicolored display displays an image. The display's ability to change angle and direction to capture images are limited by design. Referring to FIG. 1a, a conventional multimedia mobile phone has a body 11, a sensor 13 and a display 15. The display 15 and the sensor 13 are disposed on the same surface of the body 11 providing self-capture capability. When capturing, the unit cannot preview images on the display. As displayed in FIGS. 1b and 1c, another type of conventional multimedia mobile phone has a body 11′, with a sensor 13′ and a display 15′ disposed on different surfaces of the body 11′, allowing operation in a normal capture mode. It cannot, however, operate in a self-capture mode.

Other disadvantages of conventional mobile phones with multicolored display and sensor can include wasted space and possible damage to the exposed sensors.

### SUMMARY OF THE INVENTION

An object of the present invention is to provide an electronic device with a rotating member on which a sensor and a display are both disposed on different surfaces. This design saves power, the rotating member allows capture of images from different angles and directions, and the sensors are protected.

The present invention provides an electronic device with display and sensor. The device comprises a body, a rotating member, a first display, and a sensor. The rotating member is rotatably connected to the body having first and second surfaces. The first display is disposed on the first surface of the rotating member and the sensor is disposed on the second surface thereof. The sensor allows capture of images when rotated on the rotating member.

The present invention also provides another form of electronic device with display and sensor, comprising a body, a rotating member, a first display, a second display, and a sensor. The rotating member is rotatably connected to the body, having first and second surfaces. The first display is disposed on the first surface of the rotating member and the sensor is disposed on the second surface of the rotating member. The second display is disposed on the body. The sensor captures images and displays them on the second display.

### DESCRIPTION OF THE DRAWINGS

The present invention can be more fully understood by reading the subsequent detailed description in conjunction with the examples and references made to the accompanying drawings, wherein:

FIG. 1a is a schematic diagram displaying a conventional multimedia mobile phone;

FIG. 1b is a schematic diagram displaying another type of conventional multimedia mobile phone;

FIG. 1c displays the back of the multimedia mobile phone in FIG. 1b;

FIG. 2a is a schematic diagram displaying an electronic device with display and sensor of the present invention;

FIG. 2b displays a cross section along IIb-IIb′ line of FIG. 2a.

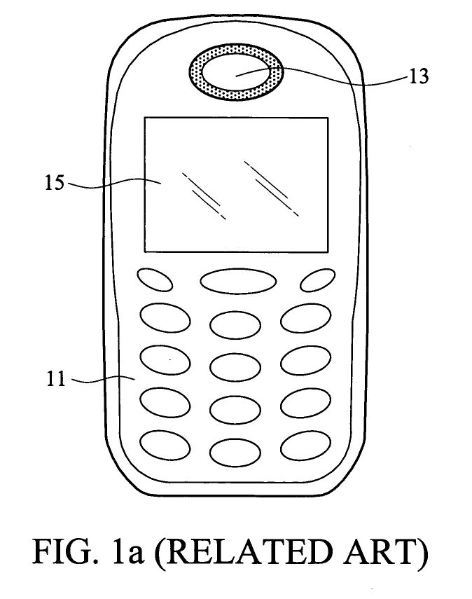

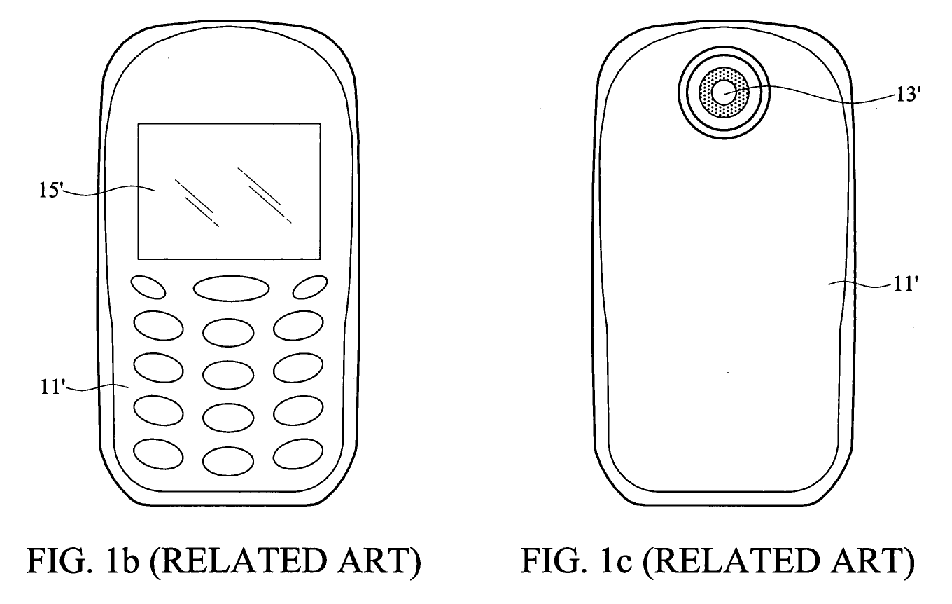

### DETAILED DESCRIPTION OF THE INVENTION

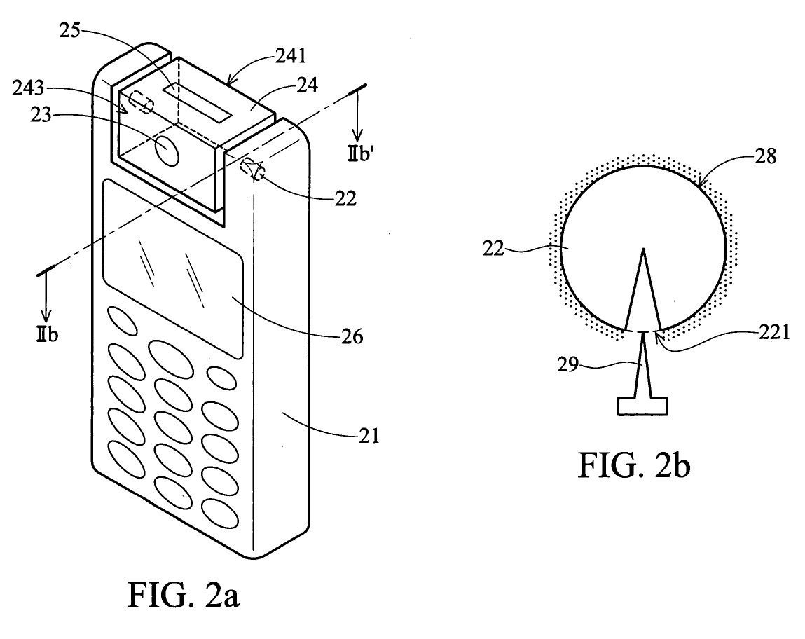

FIGS. 2a and 2b depict a first embodiment of an electronic device with display and sensor. FIG. 2a is a schematic diagram displaying an electronic device with display and sensor of the present invention. FIG. 2b displays a cross section along IIb-IIb′ of FIG. 2a.

The present invention is an electronic device with display and sensor. The device includes a body 21, a sensor 23, a rotating member 24, and a first display 25. The sensor 23 is a CMOS sensor and the device is a mobile phone in the embodiment.

The rotating member 24 has first and second surfaces and is rotatably connected to the body 21. In this embodiment, the rotating member 24 has a shaft 22 rotatably connected to the body 21. The first display 25 and the sensor 23 are disposed on the first surface 241 and the second surface 243 of the rotating member 24, respectively. The sensor 23 allows capture of images from multiple angles when the rotating member 24 is rotated.

Furthermore, a second display 26 is disposed on the body 21. When the sensor 23 receives the image, the second display 26 displays the image. The rotating member 24 allows capture of images from different angles and directions. In a self-capture mode, the sensor 23 and the second display 26 face the same direction by rotating the rotating member 24. Thus, users can preview the image and revise the angle before capture by checking the second display 26. In a normal capture mode, the sensor 23 and the second display 26 face different directions by rotating the rotating member 24. Thus, the sensor 23 captures the image and the second display 26 displays the image. When capture is disabled, the second display 26 enters a standby mode, and the rotating member 24 is rotated to a predetermined angle so that the sensor 23 faces the body 21. Standby mode turns off the second display 26. The first display 25 can display text messages only, such as signal level, calling numbers and battery level for power saving purposes. When the sensor 23 and the second display 26 are disabling, the electric device can be operated with the first display 25 normally and power saving.

FIG. 2b displays an example of power control for the second display 26. FIG. 2b is a local enlarged view along line IIb-IIb′ of FIG. 2a.

A first metal contact portion 28 is formed on the shaft 22, which has a notch 221. A second pointed metal contact portion 29 is disposed on the body 21. The second display 26 is turned on when the first metal contact portion 28 contacts the second metal contact portion 29, and the second display 26 is turned off when the first metal contact portion 28 is separated from the second metal contact portion 29. When additional functions are performed, the power of the second display 26 is not turned off. If the device is idle, the second display 26 enters a standby mode. Thus, the notch 221 of the shaft 221 aligns with the second metal contact portion 29 when the sensor 23 faces the body 21 by rotating the rotating member 24. That is the first metal contact portion 28 is separated from the second metal contact portion 29, and power thereto is turned off. The notch 221 of the shaft 221 does not align with the second metal contact portion 29 when the sensor 23 faces directions other than the body 21.

Thus, the sensor 23 is hidden when the sensor 23 faces the body 21. This design protects the lens of the sensor 23 from damage. At the same time, the second display 26 enters a standby mode, and critical messages, such as signal level, time, and battery level are displayed on the first display 25. The first display 25 is smaller than the second display 26, and is not necessary multicolored. Thus, the power consumption of the first display 25 is less than the second display 26.

As mentioned above, the power control of the second display by the first and the second metal contact portion is described here as one example. Other switching device or detection circuit configurations are applicable.

As mentioned, advantages of the electronic device of the present invention include no need to supply power to a large display continuously, as messages are displayed on the smaller display when the multimedia function is not in use, such that standby time is substantially increased. Also, since the sensor and the display are rotatable, the device is simpler and more easily operated, and the sensor and display's integration with the rotating member reduces size of the device. As well, the rotatable disposition allows capture of images from different angles and directions, and provides protection of the sensor lens.

Finally, when the invention has been described by way of example and in terms of the preferred embodiments, it is to be understood that the invention is not limited to the disclosed embodiments. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. An electronic device, comprising:
a body;
a rotating member rotatably connected to the body and having first and second surfaces;
a first display disposed on the first surface of the rotating member; and
an image capture sensor disposed on the second surface of the rotating member, to allow capture of images from multiple angles when the rotating member is rotated.

2. The electronic device as claimed in claim 1, further comprising a second display disposed on the body, to display an image captured by the sensor.

3. The electronic device as claimed in claim 1, wherein the second display enters a standby mode when the rotating member is rotated to a predetermined angle at which the sensor faces the body.

4. The electronic device as claimed in claim 3, wherein in standby mode the second display is disabled.

5. The electronic device as claimed in claim 1, wherein the rotating member comprises a first metal contact portion and the body comprises a second metal contact portion, and the second display is enabled when the first metal contact portion contacts the second metal contact portion, and the second display enters a standby mode when the first metal contact portion is separated from the second metal contact portion.

6. The electronic device as claimed in claim 5, wherein the rotating member has a shaft rotatably connected to the body, and the first metal contact portion is formed on the shaft.

7. The electronic device as claimed in claim 6, wherein the shaft has a notch interrupting the surface of the second contact portion, such that the first metal contact portion separates from the second metal contact portion when the notch aligns with the second metal contact portion.

8. The electronic device as claimed in claim 7, wherein the second metal contact portion is pointed.

9. The electronic device as claimed in claim 1, wherein the sensor is a CMOS sensor.

10. The electronic device as claimed in claim 1, wherein the electronic device is a mobile phone.

11. An electronic device with display and sensor, comprising:
a body;
a rotating member rotatably connected to the body and having first and second surfaces;
a first display disposed on the first surface of the rotating member;
a second display disposed on the body; and
a sensor disposed on the second surface of the rotating member, to capture an image and display it on the second display,
wherein the second display enters a standby mode when the second surface of the rotating member is rotated to face the body.

12. The electronic device as claimed in claim 11, wherein the electronic device is a mobile phone.

13. The electronic device as claimed in claim 12, wherein when the second display enters a standby mode, the first display displays a plurality of text messages.
